(19) United States
(12) Patent Application Publication
(10) Pub. No.: US 2024/0113730 A1
(43) Pub. Date: Apr. 4, 2024

(54) Circuits And Methods For Converting Between Data Formats And Data Filtering

(71) Applicant: Altera Corporation, San Jose, CA (US)

(72) Inventors: Maghawan Punde, Pune (IN); Mark Lewis, Marlow (GB)

(73) Assignee: Altera Corporation, San Jose, CA (US)

(21) Appl. No.: 18/526,940

(22) Filed: Dec. 1, 2023

(51) Int. Cl. H03M 7/30

(52) U.S. Cl. CPC H03M 7/6005; H03M 7/3066

(57) ABSTRACT

An integrated circuit includes conversion circuitry for converting first data in a first data format optimized for efficient data storage into second data in a second data format optimized for processing by a processing circuit. The integrated circuit also includes filter circuitry for filtering the second data to generate filtered data in the second data format. The integrated circuit outputs the filtered data for processing by the processing circuit.

### TECHNICAL FIELD

The present disclosure relates to electronic integrated circuits, and more particularly, to techniques for converting between data formats and data filtering.

### BACKGROUND

Configurable integrated circuits can be configured by users to implement desired custom logic functions. In a typical scenario, a logic designer uses computer-aided design (CAD) tools to design a custom circuit design. When the design process is complete, the computer-aided design tools generate configuration data. The configuration data is then loaded into configuration memory elements that configure configurable logic circuits in the integrated circuit to perform the functions of the custom circuit design. Configurable integrated circuits can be used for co-processing in big-data or fast-data applications. For example, configurable integrated circuits can be used in application acceleration tasks in a datacenter and can be reprogrammed during datacenter operation to perform different tasks.

### BRIEF DESCRIPTION OF DRAWINGS

FIG. 1 depicts a diagram of a system for transcoding data in a database from a storage optimized data format to a processing optimized data format with inline filtering.

FIG. 2 depicts a diagram that illustrates examples of a host and a hardware transcoder that has a scalable host controller interface for converting data in data pages in a database from a storage optimized data format to a processing optimized data format.

FIG. 3 depicts another diagram of a system for converting data in a database from a storage optimized data format to a processing optimized data format and filtering the data.

FIG. 4 depicts a flow chart that illustrates examples of operations that can be performed to convert data in a database from a storage optimized data format to a processing optimized data format and to filter the data.

FIG. 5 illustrates an example of a programmable logic integrated circuit (IC) that can include the circuitry disclosed herein with respect to any of FIGS. 1-3.

FIG. 6A illustrates a block diagram of a system that can be used to implement a circuit design to be programmed onto a programmable logic device using design software.

FIG. 6B is a diagram that depicts an example of the programmable logic device that includes three fabric die and two base die that are connected to one another via microbumps.

FIG. 7 is a block diagram illustrating a computing system configured to implement one or more aspects of the embodiments described herein.

### DETAILED DESCRIPTION

In recent years, performance-oriented database systems have been developed for online analytical processing (OLAP) workloads. These workloads are designed to extract useful high-level insights from large amounts of data. Analytical queries on large amounts of data typically only select a single, or a small fraction, of all rows, and usually only consider a small subset of all the columns. Such queries are thus point or range queries, whereby data is filtered via equality or range predicates and joins between fact and dimension tables.

Databases are often stored in storage in storage optimized data (or database) formats such as Apache Parquet, which is a column-oriented data file format designed for space efficient data storage and retrieval. As used herein, “storage” refers to non-volatile archival storage circuits or devices, such as non-volatile solid-date memory devices or hard disks. Databases, or portions thereof, can also be stored in memory in processing optimized data (or database) formats, such as Apache Arrow, which is a language-independent columnar memory format for flat and hierarchical data that is organized for efficient analytic processing operations performed by processing integrated circuits, such as central processing units (CPUs), programmable integrated circuits, and graphics processing units (GPUs). As used herein, “memory” refers to a volatile or non-volatile memory circuit or device that is accessible by a processing integrated circuit (IC) to perform processing operations. The memory circuit or device may be, as examples, in the same IC as the processing IC (such as random access memory (RAM)), coupled to the same circuit board as the processing IC but in a separate IC (e.g., cache memory), or coupled to a different circuit board than the processing IC but housed in the same computer.

Storage optimized data formats, such as Apache Parquet, may arrange data in pages and store metadata per page, including the minimum and maximum values contained. Most software engines that process databases feature a form of coarse-grained predicate pushdown, in which these minimum and maximum value statistics are leveraged to selectively skip pages. Skipping based on minimum and maximum values is effective only if there is a natural ordering to the values. Any non-skippable part of the data still has to be fully scanned.

According to some examples discloses herein, a hardware engine is provided for transcoding between database formats and incorporating predicate pushdown, such as filtering, to improve efficiency. In some exemplary implementations, the hardware engine converts data in a database from a storage optimized data format to a processing optimized data format and filters the data. In these implementations, a subset of a large database can be efficiently extracted from storage for processing by a processor IC. A hardware engine that offloads data for transcoding with fine grained filtering can improve the cost of ownership for cloud users.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs). As discussed herein, an integrated circuit (IC) can include hard logic and/or soft logic. As used herein, “hard logic” generally refers to circuits in an integrated circuit device that are not configurable by an end user. The circuits in an integrated circuit device (e.g., in a configurable logic IC) that are configurable by the end user are referred to as “soft logic.”

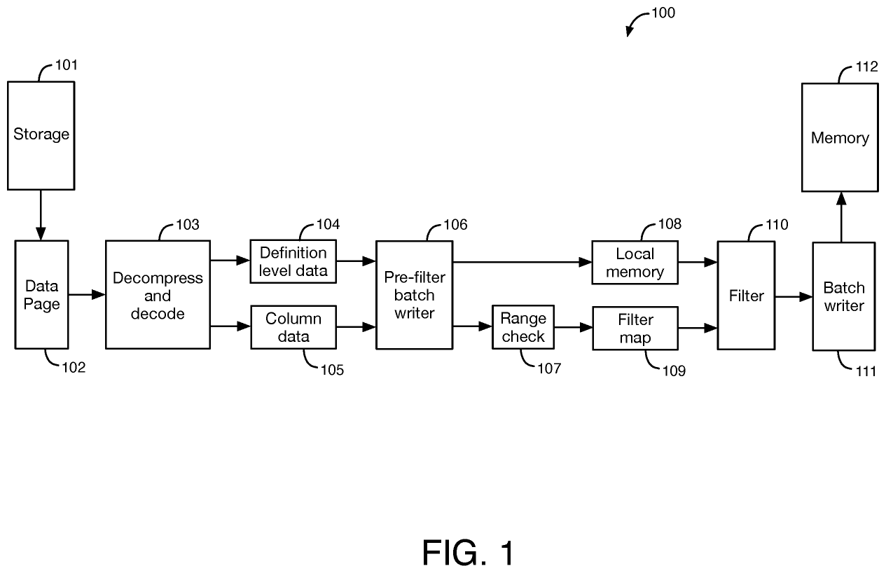

FIG. 1 depicts a diagram of a system 100 for transcoding data in a database from a storage optimized data format to a processing optimized data format with inline filtering. The system 100 shown in Figure (FIG. 1 includes hardware circuitry. The hardware circuitry of system 100 includes storage device 101, decompress and decode circuitry 103, pre-filter batch writer circuitry 106, range check circuitry 107, local memory 108, filter map memory 109, filter circuitry 110, batch writer circuitry 111, and memory device 112. The system 100 is configured or configurable to perform various functions associated with converting data in a database between data formats as described below. The system 100 can include, for example, one or more integrated circuits (ICs), such as one or more central processing unit (CPU) or microprocessor ICs, graphics processing unit (GPU) ICs, programmable logic ICs (e.g., field programmable gate arrays), etc. System 100 is also referred to as a hardware engine.

In the example of FIG. 1, a data page 102 in a storage optimized data format is accessed from a database stored in storage device 101 (and optionally stored in memory). The storage optimized data format may be, for example, Apache Parquet. The data page 102 is compressed and encoded according to the storage optimized data format. The decompress and decode circuitry 103 then decompresses the data page and performs a definition level data decode on the data page to generate decoded definition level data 104. The decompress and decode circuitry 103 also performs a column data decode on the data page to generate decoded column data 105. The decoded column data 105 and decoded definition level data 104 are correlated by software to insert Null values.

Pre-filter batch writer circuitry 106 then transcodes the correlated column data 105 and the decoded definition level data 104 to form one or more record batches (e.g., Apache Arrow record batches) of the data page that are in a processing optimized data format (e.g., Apache Arrow). The record batches of the data page are stored in local memory 108. Thus, the pre-filter batch writer circuitry 106 converts the data page from the storage optimized data format to the processing optimized data format. In some implementations that are described herein as an example, each data page remains a separate data page after transcoding (e.g., two or more data pages are not coalesced into one data page), all the data in a data page belong to one column, and all the data in a record batch belong to one column.

The range check circuitry 107 then applies a filter condition to the record batches. The filter condition is expressed as an accumulation of range checks. The filter condition is associated with a row in the record batches. As an example, the range check circuitry 107 can apply the range checks to the records batches to determine if values of the data in the record batches are within ranges of values that are defined by the range checks. The range check circuitry 107 applies the range checks to the record batches to generate range check results, while writing the record batches that are in the processing optimized data format.

The range check results are accumulated as a bit vector (i.e., a filter map) that is stored in filter map memory 109. Filter circuitry 110 then filters rows in the record batches that are in the processing optimized data format using the filter map accessed from filter map memory 109 to generate filtered record batches. The filter circuitry 110 uses the filter map in filter map memory 109 to accept each row in the record batches stored in local memory 108 having data within the ranges indicated by all of the range checks. Only the accepted rows having data within the ranges indicated by all of the range checks are added to the filtered record batches. Rows in the record batches that fail any one range check are dropped and not added to the filtered record batches. Batch writer circuitry 111 then writes the filtered record batches that are in the processing optimized data format into the memory device 112.

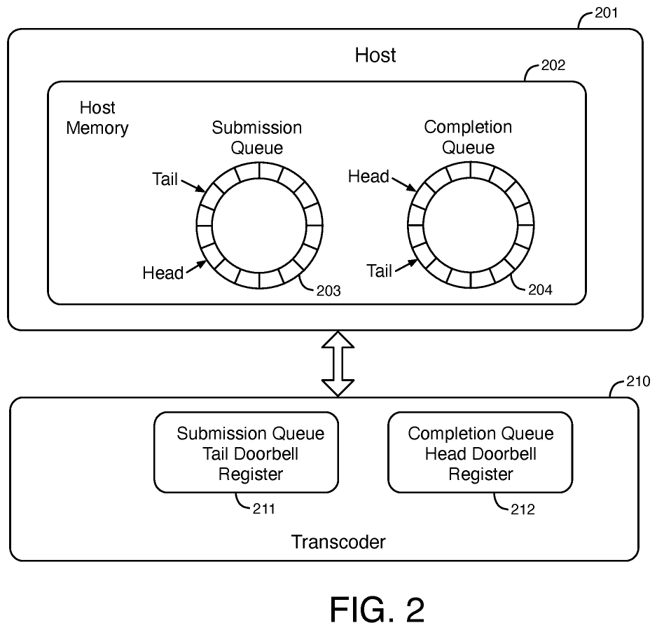

FIG. 2 depicts a diagram that illustrates examples of a host 201 and a hardware transcoder 210 that has a scalable host controller interface for converting data in data pages in a database from a storage optimized data format to a processing optimized data format. The scalable host controller interface provides an optimized command issue and completion path. The host 201 includes a host memory 202 (e.g., memory device 112). The host memory 202 includes a submission queue (SQ) 203 and a completion queue (CQ) 204. The hardware transcoder 210 includes a submission queue tail doorbell register 211 and a completion queue head doorbell register 212.

The submission queue (SQ) 203 is a circular buffer with a fixed slot size that software in the host 201 uses to submit commands for execution by hardware transcoder 210 to convert data in data pages accessed from a database from a storage optimized data format to a processing optimized data format. SQ 203 stores head and tail pointers to the data in the storage optimized data format in the one or more data pages accessed from the database. SQ 203 also stores commands for converting the data between data formats. SQ 203 functions as a message carrier interface that transmits pointers between the software of the host 201 and the hardware transcoder 210 that converts between data formats.

As used herein, a doorbell refers to a type of interrupt for hardware or software. Each time that the software in the host 201 submits a new command to the submission queue 203, a doorbell is triggered (i.e., a new tail doorbell) that indicates to the hardware transcoder 210 that the new command is stored in the submission queue 203. The host 201 updates the SQ tail doorbell register 211 in response to each new tail doorbell when there are one to N new commands to execute, where N is any positive integer. The previous SQ tail value is overwritten in the hardware transcoder 210 when there is a new write to the SQ tail doorbell register 211. Each submission queue 203 entry includes a command. In response to each new tail doorbell that is triggered, the hardware transcoder 210 fetches the associated new command from the submission queue 203 using the pointer that points to the new command (e.g., the head or tail pointer) in the submission queue 203. The hardware transcoder 210 fetches SQ commands in order from the submission queue 203 using the pointers and executes those commands in submission order. The hardware transcoder 210 executes each of the commands by converting the data associated with each of the commands from the storage optimized data format (e.g., Apache Parquet) to the processing optimized data format (e.g., Apache Arrow).

The completion queue (CQ) 204 is a circular buffer with a fixed slot size used to post status for completed commands. CQ 204 stores head and tail pointers to the data in the data page(s) that have been converted by the hardware transcoder 210 into the processing optimized data format. The CQ 204 functions as a message carrier interface that transmits pointers between the hardware transcoder 210 that converts between data formats and the software of the host 201. A completed command is uniquely identified by a command identifier that is assigned by the host software. The host software updates the CQ head pointer after transcoder 210 has executed completed commands and indicates the last free CQ entry. When the hardware transcoder 210 completes processing for converting the data into the processing optimized data format, the hardware transcoder 210 writes a message into the CQ 204 and issues a doorbell for the host software (i.e., a new head doorbell). The host 201 updates the CQ head doorbell register 212 in response to each new head doorbell.

An exemplary implementation of the host software can have independent threads to handle submission and completion. Examples of operations for a submission software thread are now described. In operation 1, the submission software thread reads and parses a footer in a data file for data stored in the storage optimized data format, the row group and the column metadata to determine the number of row groups in the data, and the columns and the column chunk starting positions in the data file. Based on a filter condition in a query, the submission software thread determines in operation 2 which rows groups in the data should be transcoded from the storage optimized data format into the processing optimized data format. Based on the filter condition in the query, the submission software thread determines in operation 3 which of the column chunks in the storage optimized data format should be converted into the processing optimized data format. In operation 4, the submission software thread then configures a hardware transcoder (e.g., a hardware accelerator) with the filter condition expression. In operation 5, the submission software thread reads the column chunk into the host memory. In operation 6, the submission software thread then assembles the submission command for a data page in the column chunk, writes the submission command to the head of submission queue 203, and rings a doorbell to notify the hardware transcoder that a new command is available. In operation 7, the submission software thread repeats operations 5 and 6 for all pages of a given column chunk. In operation 8, the submission software thread repeats operations 5, 6, and 7 for selected row groups.

Examples of operations for a completion software thread are now described. In operation 1, the completion software thread waits for a new completion notification from the hardware transcoder (e.g., a hardware accelerator). In operation 2, the completion software thread pops a descriptor for a data record from the head of the completion queue 204. In operation 3, the completion software thread populates a pointer to the data record into an application data structure. In operation 4, the completion software thread then repeats operation 1 for the next command.

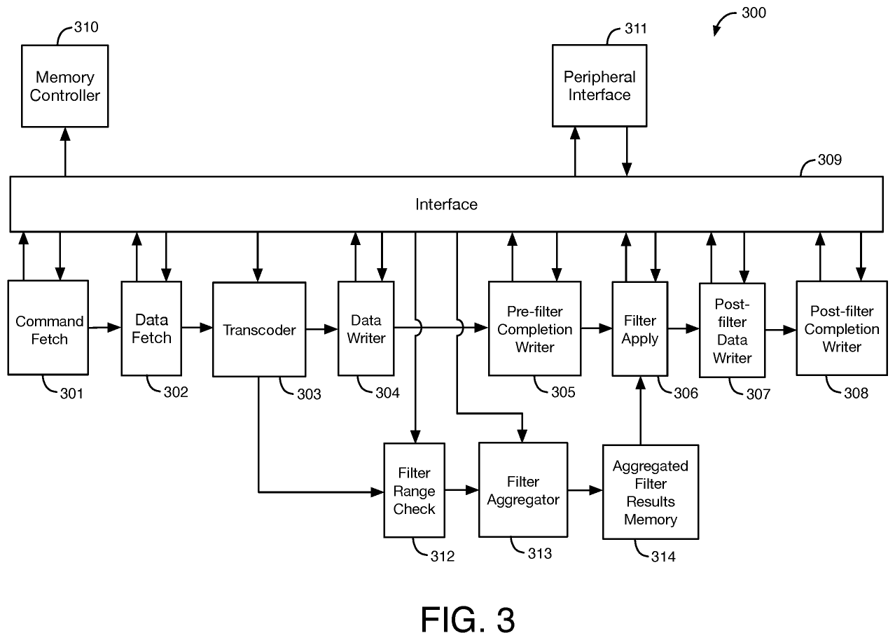

FIG. 3 depicts a diagram of a system 300 for converting data in a database from a storage optimized data format to a processing optimized data format and filtering the data. The system of FIG. 3 includes command fetch circuitry 301, data fetch circuitry 302, transcoder circuitry 303, data writer circuitry 304, pre-filter completion writer circuitry 305, filter apply circuitry 306, post-filter data writer circuitry 307, post-filter completion writer circuitry 308, interface 309, memory controller circuit 310, peripheral interface 311, filter range check circuitry 312, filter aggregator circuitry 313, and aggregated filter results memory 314. The system of FIG. 3 can be implemented in one or more integrated circuits (ICs), such as one or more central processing unit (CPU) or microprocessor ICs, graphics processing unit (GPU) ICs, programmable logic ICs (e.g., field programmable gate arrays) using soft logic, etc.

Initially, the system 300 waits for the host software to submit a new command to convert data from a database between data formats and to ring a doorbell for the submission queue 203. After a new command is stored in the submission queue 203 from the host memory through interface 309 and peripheral interface 311, the command fetch circuitry 301 reads the new command at the head of the submission queue 203. Next, the data fetch circuitry 302 reads a data page of the database from the host memory into memory in system 300 (e.g., memory in a processing integrated circuit) through interface 309 and peripheral interface 311 using address pointers in the new command.

The transcoder circuitry 303 decompresses the data page stored in the memory, gets a definition level data length from a portion (e.g., 4 bytes) of the data page, gets a run length of the next encoded segment of the definition level data, and then decodes the definition level data segment using run length encoding (RLE). RLE is a form of data compression that compress a same data bit value that occurs in a sequence of multiple consecutive bits in input data. The transcoder circuitry 303 repeats the operations of getting a run length of the next encoded segment of the definition level data and decoding the definition level data segment, until all of the definition level data segments are decoded. The transcoder circuitry 303 then decodes the column data in the data page. All of the data in the data page is in one column. The transcoder circuitry 303 then transcodes the decoded column data in the data page and the decoded definition level data from the storage optimized data format into unfiltered transcoded data (e.g., in one or more record batches) that is in the processing optimized data format (e.g., Apache Arrow format). Data writer circuitry 304 stores the unfiltered transcoded data in memory in system 300 (e.g., memory attached to the integrated circuit). One or more descriptors containing metadata and pointers to the memory where the unfiltered transcoded data is written are stored by the pre-filter completion writer circuitry 305 in the completion queue 204.

While the transcoder circuitry 303 is transcoding the decoded column data and the decoded definition level data from the storage optimized data format into the processing optimized data format, the filter range check circuitry 312 evaluates a filter condition associated with each row of the data and saves an accumulated result in memory (e.g., in the integrated circuit). The filter condition evaluated by the filter range check circuitry 312 is expressed as an accumulation of range checks of each row of the data page. As an example, the filter range check circuitry 312 can apply each range check to a column in the data page to determine if values of the data in the column are within a range of values that are defined by the range check. The filter range check circuitry 312 applies the range checks to the columns in each data page to generate range check filter results, while the data from the data page is transcoded into the processing optimized data format. The range checks are applied as data pages are received, but the final result of the filter condition is not determined until all of the range checks are evaluated by filter apply circuitry 306, as described below.

The filter aggregator circuitry 313 aggregates the range check filter results and stores the aggregated range check filter results as a filter map in memory 314. The operations performed by circuitry 301-305 and 312-314 are repeated, until the columns of given row groups in the data page are transcoded into the processing optimized data format.

The filter apply circuitry 306 accesses the transcoded data in the processing optimized data format using the pointers to the memory where the transcoded data is stored. The filter apply circuitry 306 then filters the transcoded data using the filter map to generate filtered transcoded data. The filter apply circuitry 306 uses the aggregated range check filter results (i.e., the filter map) stored in memory 314 to filter the transcoded data page to generate the filtered transcoded data by selecting only the data of interest from the data page to add to the filtered transcoded data. The filter apply circuitry 306 uses the filter map to determine which data in the data page is filtered-in or filtered-out to generate the filtered transcoded data. The filter apply circuitry 306 uses the filter map to accept each row having data within the ranges indicated by all of the range checks. Only the accepted rows having data within the ranges indicated by all of the range checks are added to the filtered transcoded data. Rows that fail any one range check are dropped. Columns are not dropped based on the filter conditions. Post-filter data writer circuitry 307 then writes the filtered transcoded data in the processing optimized data format to the host memory through interface 309. One or more descriptors containing metadata and pointers to the host memory where the filtered transcoded data is written are stored by the post-filter completion writer circuitry 308 at the tail of the completion queue 204. The memory controller circuit 310 then generates an interrupt to notify the host software.

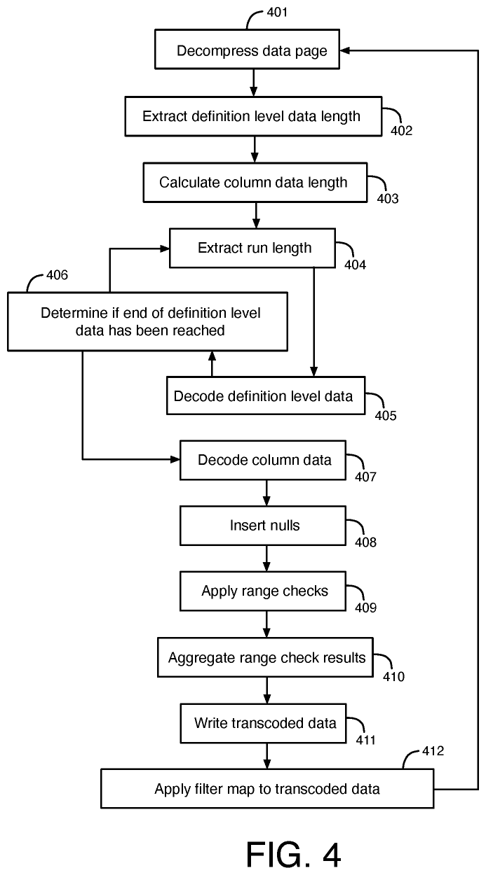

FIG. 4 depicts a flow chart that illustrates examples of operations that can be performed to convert data in a database from a storage optimized data format into a processing optimized data format and to filter the data. The operations of FIG. 4 can be performed, for example, by the circuitry of FIG. 1 or FIG. 3. In operation 401, a data page that has been accessed from the database is decompressed to generate decompressed data. In operation 402, a length of the definition level data is extracted from the decompressed data. The definition level data are metadata associated with each of the columns of the decompressed data. In operation 403, a length of the column data is calculated from the decompressed data. The column data are data entries in columns of the decompressed data.

In the example of FIG. 4, the data page accessed from the database is encoded using run length encoding (RLE). In RLE, a single data bit value (e.g., 0 or 1) that occurs in a sequence of multiple consecutive bits in input data is encoded by an encoder to generate a single output data bit value and a run length equal to the number of times the single data bit value occurred in the sequence of multiple consecutive bits in the input data. In operation 404, the run length is extracted for a data bit value in the decompressed data that has been encoded using RLE. The run length extracted in each iteration of operation 404 is accumulated (i.e., summed) with the run lengths extracted in previous iterations of operation 404 to generate an accumulated run length.

Then in operation 405, a portion of the definition level data is decoded using the run length extracted in operation 404 and a data bit value associated with the run length. In operation 406, a determination is made whether the end of the definition level data in the data page has been reached based on the accumulated run length determined in the iterations of operation 404. If the accumulated run length is less than the length of the definition level data, then operations 404-406 are repeated until the accumulated run length equals the length of the definition level data in order to decode each sequence of data bits encoded using RLE. If the accumulated run length is greater than or equal to the length of the definition level data, then in operation 407, the column data is decoded (e.g., using RLE decoding). In operation 408, null values are inserted into the decoded column data generated in operation 407 in positions that lack a data value. In operations 407-409, the decoded data is converted from the storage optimized data format into the processing optimized data format to generate transcoded data.

In operation 409, range checks are applied to the decoded column data and definition level data (e.g., using range check circuitry 107 or 312) using a filter condition that is expressed as an accumulation of range checks of the decompressed data. In operation 410, the range check results generated by applying the range checks in operation 409 are aggregated (e.g., by the filter aggregator circuitry 313) and stored in memory as a filter map. In operation 411, the transcoded data in the processing optimized data format is stored in memory. In operation 412, the rows in the transcoded data are filtered using the filter map generated in operation 410 to generate filtered transcoded data (e.g., using filter circuit 110 or filter apply circuitry 306), for example, as described herein with respect to FIGS. 1 and 3. Operations 401-412 are then repeated for additional data pages accessed from the database. After all of the data pages accessed from the database are processed in operations 401-412, the filtered and transcoded data from all of the data pages generated in operations 401-412 are output (e.g., to a host system).

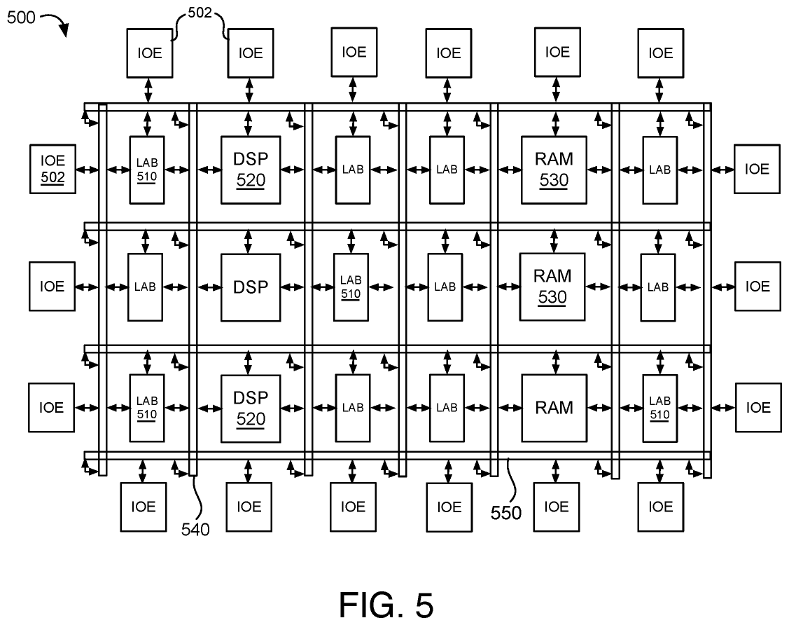

FIG. 5 illustrates an example of a programmable (i.e., configurable) logic integrated circuit (IC) 500 that can include, for example, the circuitry disclosed herein with respect to any of FIGS. 1-3. Programmable IC 500 can also be configured to perform the operations of FIG. 4. As shown in FIG. 5, the programmable logic integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals. The configurable functional circuit blocks shown in FIG. 5 can, for example, be configured to perform the functions of any of the circuitry disclosed herein with respect to FIGS. 1-3 and/or the operations of FIG. 4.

In addition, programmable logic IC 500 can have input/output elements (IOEs) 502 for driving signals off of programmable logic IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the programmable logic IC 500 can have input/output elements 502 arranged in different ways. For example, input/output elements 502 can form one or more columns, rows, or islands of input/output elements that may be located anywhere on the programmable logic IC 500.

The programmable logic IC 500 can also include programmable interconnect circuitry in the form of vertical routing channels 540 (i.e., interconnects formed along a vertical axis of programmable logic IC 500) and horizontal routing channels 550 (i.e., interconnects formed along a horizontal axis of programmable logic IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein with respect to FIGS. 1-4 can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Programmable logic IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), look-up tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, programmable logic IC 500 can include configuration memory that is organized in sectors, whereby a sector can include the configuration RAM bits that specify the functions and/or interconnections of the subcomponents and wires in or crossing that sector. Each sector can include separate data and address registers.

The programmable logic IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPGAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

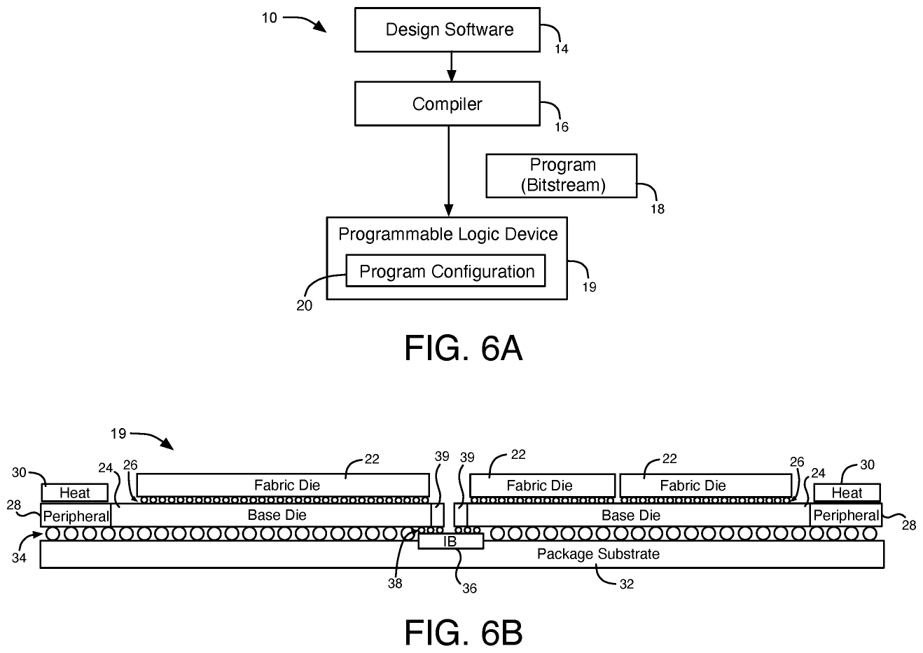

FIG. 6A illustrates a block diagram of a system 10 that can be used to implement a circuit design to be programmed into a programmable logic device using design software. A designer can implement circuit design functionality on an integrated circuit, such as a reconfigurable programmable logic device 19 (e.g., a field programmable gate array (FPGA)). The designer can implement the circuit design to be programmed into the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations to be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or another highly specialized task.

The programmable logic device 19 can represent any integrated circuit device that includes a programmable logic device. In some implementations, a programmable logic device can include two separate integrated circuit die where at least some of the programmable logic fabric is separated from at least some of the fabric support circuitry that operates the programmable logic fabric. One example of the programmable logic device 19 is shown in FIG. 6A, but many others can be used, and it should be understood that this disclosure is intended to encompass any suitable programmable logic device 19 where programmable logic fabric and fabric support circuitry are at least partially separated on different integrated circuit die.

FIG. 6B is a diagram that depicts an example of the programmable logic device 19 that includes three fabric die 22 and two base die 24 that are connected to one another via microbumps 26. In the example of FIG. 6B, at least some of the programmable logic fabric of the programmable logic device 19 is in the three fabric die 22, and at least some of the fabric support circuitry that operates the programmable logic fabric is in the two base die 24. For example, some of the circuitry of configurable IC 500 shown in FIG. 5 (e.g., LABs 510, DSP 520, RAM 530) can be located in the fabric die 22 and some of the circuitry of IC 500 (e.g., input/output elements 502) can be located in the base die 24.

Although the fabric die 22 and base die 24 appear in a one-to-one relationship or a two-to-one relationship in FIG. 6B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

The fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

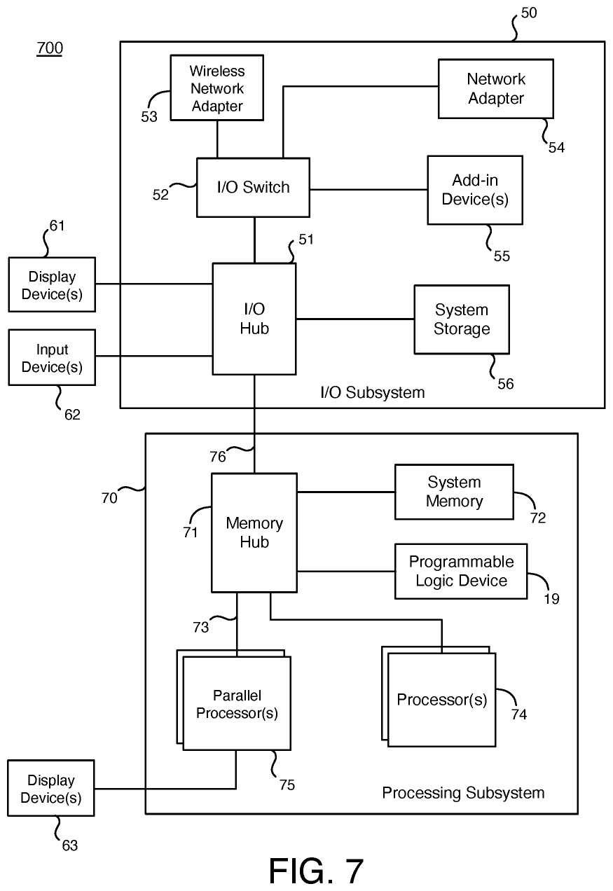

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is an integrated circuit comprising: conversion circuitry for converting first data in a first data format optimized for efficient data storage into second data in a second data format optimized for processing by a processing circuit; and filter circuitry for filtering the second data to generate filtered data in the second data format, wherein the integrated circuit outputs the filtered data for processing by the processing circuit.

In Example 2, the integrated circuit of Example 1 further comprises memory for storing the first data in the first data format, wherein the first data format and the second data format are designed for a database.

In Example 3, the integrated circuit of any one of Examples 1-2 further comprises decompression circuitry for decompressing third data accessed from a database to generate fourth data; and decoding circuitry for decoding the fourth data to generate the first data.

In Example 4, the integrated circuit of any one of Examples 1-3 may optionally include wherein the filter circuitry applies a range check to a portion of the second data to determine if first values of the second data in the portion are within a range of second values defined by the range check.

In Example 5, the integrated circuit of any one of Examples 1-4 may optionally include wherein the filter circuitry applies range checks to portions of the second data to generate range check results and aggregates the range check results to generate a filter map.

In Example 6, the integrated circuit of Example 5 may optionally include wherein the filter circuitry filters the portions of the second data using the filter map to generate the filtered data.

In Example 7, the integrated circuit of any one of Examples 5-6 may optionally include wherein the filter circuitry evaluates the range checks using definition level data and column data in the second data.

In Example 8, the integrated circuit of any one of Examples 1-7 may optionally include wherein a submission queue stores commands for converting the first data to the second data format.

In Example 9, the integrated circuit of Example 8 further comprises a doorbell register, wherein the conversion circuitry fetches one of the commands and executes the one of the commands by converting the first data into the second data in response to a doorbell stored in the doorbell register.

In Example 10, the integrated circuit of any one of Examples 1-9 may optionally include wherein a completion queue stores pointers to the filtered data in the second data format.

In Example 11, the integrated circuit of Example 10 further comprises a doorbell register, wherein the conversion circuitry writes a message into the completion queue and issues a doorbell that is stored in the doorbell register in response to converting the first data into the second data.

Example 12 is a method for converting between first and second data formats, the method comprising: converting first data in the first data format optimized for space efficient storage into second data in the second data format optimized for processing operations using a transcoder circuit; and filtering the second data to generate filtered data in the second data format using a filter circuit.

In Example 13, the method of Example 12 may optionally include wherein filtering the second data to generate the filtered data further comprises: applying a range check to a portion of the second data to determine if first values of the second data in the portion are within a range of second values defined by the range check.

In Example 14, the method of any one of Examples 12-13 may optionally include wherein filtering the second data to generate the filtered data further comprises: applying range checks to portions of the second data to generate range check results; aggregating the range check results to generate a filter map; and filtering the portions of the second data using the filter map to generate the filtered data.

In Example 15, the method of any one of Examples 12-14 further comprises: storing commands for converting the first data to the second data format in a circular buffer; fetching one of the commands stored in the circular buffer; and executing the one of the commands by converting the first data into the second data in response to a doorbell stored in a doorbell register.

In Example 16, the method of any one of Examples 12-15 further comprises: storing pointers to the filtered data in the second data format in a circular buffer; and storing a message into the circular buffer and storing a doorbell in a doorbell register in response to converting the first data into the second data.

Example 17 is a non-transitory computer readable storage medium comprising computer readable instructions stored thereon for causing an integrated circuit to: transcode first data in a storage space efficient database format into second data in a processing optimized database format; filter the second data to generate filtered data in the processing optimized database format; and output the filtered data for processing using the processing optimized database format.

In Example 18, the non-transitory computer readable storage medium of Example 17 may optionally include wherein the computer readable instructions further cause the integrated circuit to apply a range check to a portion of the second data to determine if first values of the second data in the portion are within a range of second values defined by the range check.

In Example 19, the non-transitory computer readable storage medium of any one of Examples 17-18 may optionally include wherein the computer readable instructions further cause the integrated circuit to apply range checks to portions of the second data to generate range check results, aggregate the range check results to generate a filter map, and filter the portions of the second data using the filter map to generate the filtered data.

In Example 20, the non-transitory computer readable storage medium of any one of Examples 17-19 may optionally include wherein the computer readable instructions further cause the integrated circuit to store a command for converting the first data to the processing optimized database format in a circular buffer, fetch the command from the circular buffer, and execute the command by converting the first data into the second data in response to a doorbell stored in a doorbell register.

The foregoing description of the examples has been presented for the purpose of illustration. The foregoing description is not intended to be exhaustive or to be limiting to the examples disclosed herein. In some instances, features of the examples can be employed without a corresponding use of other features as set forth. Many modifications, substitutions, and variations are possible in light of the above teachings.

What is claimed is:

1. An integrated circuit comprising:
conversion circuitry for converting first data in a first data format optimized for efficient data storage into second data in a second data format optimized for processing by a processing circuit; and
filter circuitry for filtering the second data to generate filtered data in the second data format, wherein the integrated circuit outputs the filtered data for processing by the processing circuit.

2. The integrated circuit of claim 1 further comprising:
memory for storing the first data in the first data format, wherein the first data format and the second data format are designed for a database.

3. The integrated circuit of claim 1 further comprising:
decompression circuitry for decompressing third data accessed from a database to generate fourth data; and
decoding circuitry for decoding the fourth data to generate the first data.

4. The integrated circuit of claim 1, wherein the filter circuitry applies a range check to a portion of the second data to determine if first values of the second data in the portion are within a range of second values defined by the range check.

5. The integrated circuit of claim 1, wherein the filter circuitry applies range checks to portions of the second data to generate range check results and aggregates the range check results to generate a filter map.

6. The integrated circuit of claim 5, wherein the filter circuitry filters the portions of the second data using the filter map to generate the filtered data.

7. The integrated circuit of claim 6, wherein the filter circuitry evaluates the range checks using definition level data and column data in the second data.

8. The integrated circuit of claim 1, wherein a submission queue stores commands for converting the first data to the second data format.

9. The integrated circuit of claim 8 further comprising:
a doorbell register, wherein the conversion circuitry fetches one of the commands and executes the one of the commands by converting the first data into the second data in response to a doorbell stored in the doorbell register.

10. The integrated circuit of claim 1, wherein a completion queue stores pointers to the filtered data in the second data format.

11. The integrated circuit of claim 10 further comprising:
a doorbell register, wherein the conversion circuitry writes a message into the completion queue and issues a doorbell that is stored in the doorbell register in response to converting the first data into the second data.

12. A method for converting between first and second data formats, the method comprising:
converting first data in the first data format optimized for space efficient storage into second data in the second data format optimized for processing operations using a transcoder circuit; and
filtering the second data to generate filtered data in the second data format using a filter circuit.

13. The method of claim 12, wherein filtering the second data to generate the filtered data further comprises:
applying a range check to a portion of the second data to determine if first values of the second data in the portion are within a range of second values defined by the range check.

14. The method of claim 12, wherein filtering the second data to generate the filtered data further comprises:
applying range checks to portions of the second data to generate range check results;
aggregating the range check results to generate a filter map; and
filtering the portions of the second data using the filter map to generate the filtered data.

15. The method of claim 12 further comprising:
storing commands for converting the first data to the second data format in a circular buffer;
fetching one of the commands stored in the circular buffer; and
executing the one of the commands by converting the first data into the second data in response to a doorbell stored in a doorbell register.

16. The method of claim 12 further comprising:
storing pointers to the filtered data in the second data format in a circular buffer; and
storing a message into the circular buffer and storing a doorbell in a doorbell register in response to converting the first data into the second data.

17. A non-transitory computer readable storage medium comprising computer readable instructions stored thereon for causing an integrated circuit to:
transcode first data in a storage space efficient database format into second data in a processing optimized database format;
filter the second data to generate filtered data in the processing optimized database format; and
output the filtered data for processing using the processing optimized database format.

18. The non-transitory computer readable storage medium of claim 17, wherein the computer readable instructions further cause the integrated circuit to apply a range check to a portion of the second data to determine if first values of the second data in the portion are within a range of second values defined by the range check.

19. The non-transitory computer readable storage medium of claim 17, wherein the computer readable instructions further cause the integrated circuit to apply range checks to portions of the second data to generate range check results, aggregate the range check results to generate a filter map, and filter the portions of the second data using the filter map to generate the filtered data.

20. The non-transitory computer readable storage medium of claim 17, wherein the computer readable instructions further cause the integrated circuit to store a command for converting the first data to the processing optimized database format in a circular buffer, fetch the command from the circular buffer, and execute the command by converting the first data into the second data in response to a doorbell stored in a doorbell register.
